(19) United States
(12) Patent Application Publication
(10) Pub. No.: US 2025/0243060 A1
(43) Pub. Date: Jul. 31, 2025

(54) METHOD OF MAKING BORON NITRIDE NANOTUBES AND REACTION CHAMBER THEREFORE

(71) Applicant: MICHIGAN TECHNOLOGICAL UNIVERSITY, Houghton, MI (US)

(72) Inventors: Yoke Khin Yap, Houghton, MI (US); Dongyan Zhang, Houghton, MI (US); Siqi Zhang, Houghton, MI (US); Rodney Oakley, Hancock, MI (US); Sambhawana Sharma, Houghton, MI (US); Bishnu Tiwari, Houghton, MI (US)

(21) Appl. No.: 18/847,313

(22) PCT Filed: Mar. 16, 2023
(86) PCT No.: PCT/US2023/015397

§ 371 Date: Sep. 16, 2024

Related U.S. Application Data
(60) Provisional application No. 63/320,405, filed on Mar. 16, 2022.

(51) Int. Cl. C01B 21/064; B01J 27/138; C23C 16/02; C23C 16/34

(52) U.S. Cl. CPC C01B 21/064; B01J 27/138; C23C 16/0272; C23C 16/342; C01P 2002/72; C01P 2004/03; C01P 2004/13

(57) ABSTRACT

A reactor for catalytic chemical vapor deposition of nanotubes includes a reaction chamber configured to be placed under vacuum and at least one tube situated in the reaction chamber. The tube has a first closed end and a second open end. The reactor also includes at least one boat situated in the tube, at least one substrate situated on each of the at least one boats, and nanotube source material in each boat of the at least one boats. A method for catalytic chemical vapor deposition of boron nitride nanotubes is also disclosed.

### CROSS-REFERENCE TO RELATED APPLICATIONS

This application is the national phase entry of International Application No. PCT/US23/15397, filed Mar. 16, 2023, which claims priority to U.S. Provisional Application No. 63/320,405, filed Mar. 16, 2022, both of which are hereby incorporated herein in their entirety.

### BACKGROUND

Boron nitride nanotubes (BNNTs) have various biomedical and other applications. In some applications, BNNTs are better adapted than carbon nanotubes (CNTs) due to their electrically insulating and optically transparent nature. However, BNNTs are associated with several manufacturing challenges. Accordingly, there is a need to improv manufacturability, including the making of small-diameter BNNTs with low by-products (impurities).

### BRIEF DESCRIPTION OF THE DRAWINGS

FIG. 1 schematically shows an example reaction chamber for catalytic chemical vapor deposition of boron nitride nanotubes (BNNTs).

FIGS. 2A-B show x-ray diffraction spectra of BNNTs manufactured by a method described herein in the reaction chamber of FIG. 1.

FIGS. 3A-C show scanning electronic microscope (SEM) images of BNNTs grown on substrates in the reaction chamber of FIG. 1.

FIGS. 4A-C show SEM images of BNNTs grown on a silicon substrate with magnesium oxide, magnesium chloride (solution in water, methanol, ethanol, isopropanol etc.), and magnesium catalytic coatings in the reaction chamber of FIG. 1.

FIGS. 5A-C show SEM images of BNNTs grown with magnesium chloride catalytic coatings with an ammonia flow rate of 150 sccm, 250 sccm, and 350 sccm, respectively, in the reaction chamber of FIG. 1 at a magnification of 10×.

FIGS. 6A-F show SEM images of BNNTs grown with magnesium chloride catalytic coatings with a predetermined amount of source material in the reaction chamber of FIG. 1 at a magnification of 10×.

FIG. 7 shows an example reactor setup for the reactor of FIG. 1.

FIG. 8 shows SEM images of BNNTs grown on substrates in the example reactor setup of FIG. 7.

FIGS. 9A-C show SEM images of BNNTs grown with silicon substrates exposed to 5 mM, 2.5 mM, and 1.25 mM solutions of magnesium chloride, respectively.

FIG. 10A-B show BNNTs grown on samples in the example reactor setup of FIG. 7.

### SUMMARY

A reactor for catalytic chemical vapor deposition of nanotubes according to an exemplary embodiment of this disclosure, among other possible things includes a reaction chamber configured to be placed under vacuum and at least one tube situated in the reaction chamber. The tube has a first closed end and a second open end. The reactor also includes at least one boat situated in the tube, at least one substrate situated on each of the at least one boats, and source material in each boat of the at least one boats.

In a further example of the foregoing, the at least one tube is situated horizontally in the reaction chamber.

In a further example of any of the foregoing, the at least one substrate includes multiple substrates.

In a further example of any of the foregoing, the at least one substrate includes multiple substrates arranged in a common plane.

In a further example of any of the foregoing, the at least one substrate includes multiple stacked substrates.

In a further example of any of the foregoing, the at least one substrate is coated with a catalytic coating.

In a further example of any of the foregoing, the catalytic coating includes magnesium.

In a further example of any of the foregoing, the at least one substrate is silicon.

In a further example of any of the foregoing, the at least one boat is a ceramic boat.

In a further example of any of the foregoing, the tube has a first closed end and a second open end.

In a further example of any of the foregoing, the source material is boron- and oxygen-containing source material.

In a further example of any of the foregoing, the source material includes metal oxide powder.

A method for catalytic chemical vapor deposition of boron nitride nanotubes according to an exemplary embodiment of this disclosure, among other possible things includes orienting a tube in the reaction chamber. The tube has an open end and a closed end. The method also includes situating at least one boat in the tube, at least one silicon substrate situated on each of the at least one boats. Boton- and oxide-containing source material is arranged in the at least one boat. The method also includes heating the reaction chamber to volatilize the source material and release boron oxide into the tube; and flowing a nitrogen-containing precursor through the reaction chamber such that the nitrogen-containing precursor reacts with the boron oxide and boron nitride nanotubes are deposited onto the at least one substrate.

In a further example of the foregoing, the tube is oriented in the reaction chamber such that a direction of flow of the nitrogen-containing precursor is from the closed end of the tube towards the open end of the tube.

In a further example of any of the foregoing, the at least one silicon substrate includes a catalytic coating.

In a further example of any of the foregoing, the catalytic coating includes magnesium.

In a further example of any of the foregoing, the catalytic coating includes magnesium oxide. The magnesium oxide reacts with the silicon substrate to form Mg—Si—O complexes, the Mg—Si—O complexes acting as catalysts.

In a further example of any of the foregoing, the catalytic coating includes magnesium chloride.

In a further example of any of the foregoing, a concentration of the magnesium chloride is about 1.25 mM. A diameter of the boron nitride nanotubes is between about 10 to about 25 nm.

In a further example of any of the foregoing, the catalytic nitrogen-containing precursor is ammonia gas.

In a further example of any of the foregoing, the method includes placing the reaction chamber under vacuum.

In a further example of any of the foregoing, the boron nitride nanotubes have a diameter less than about 35 nm.

In a further example of any of the foregoing, the boron nitride nanotubes have a diameter of less than about 10 nm.

In a further example of any of the foregoing, boron nitride nanotubes deposited on a first substrate of the at least one substrates have a smaller diameter than boron nitride nanotubes deposited on a second substrate of the at least one substrates, and the first substrate is further from an exhaust situated in the reaction chamber than the second substrate.

In a further example of any of the foregoing, a first boat of the at least one boats includes a first amount of source material and a second boat of the at least one boats includes a second amount of source material that is about 50% of the source material of the first amount of source material, and wherein boron nitride nanotubes on a substrate of the at least one substrates situated on the first boat have larger diameters that boron nitride nanotubes on a substrate of the at least one substrate situated on the second boat, on average.

In a further example of any of the foregoing, a flow rate of the nitrogen precursor is about 350 sccm, and the diameter of the boron nitride nanotubes are between about 20 and about 25 nm.

### DETAILED DESCRIPTION

Boron nitride nanotubes (BNNTs) have many applications, including biomedical applications. However, manufacturing BNNTs can be challenging. The geometry (e.g., length and diameter) of the BNNTs affects their performance. For example, making BNNTs with small diameters during manufacturing would make BNNTs better adapted for some applications. However, prior art methods of manufacturing BNNTs do not generally provide BNNTs with small diameters (less than about 35 nm) and high purity. Nor do the prior art methods allow for controlling BNNT diameter. For example, some manufacturing processes introduce by-products/impurities to the BNNTs which can compromise their performance. This application relates to a method of employing catalytic chemical vapor deposition (CCVD) to manufacture BNNTs with relatively pure and small diameters (less than about 35 nm, and in some examples, less than about 10 nm) compared to prior art methods, and a reactor therefore.

CCVD is a method of depositing nanoscale solid materials. In general, for CCVD, a substrate is exposed to volatile precursors of the desired material in a reaction chamber. The precursors interacted with the nanoscale catalysts on the substrate and segregated as the desired nanoscale solid material, according to the general understanding in the field.

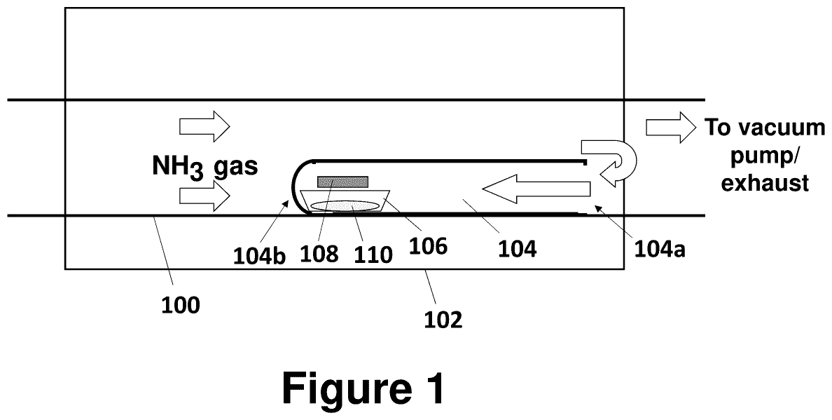

FIG. 1 shows an example reaction chamber 100 for CCVD of BNNTs. In this example, reaction chamber 100 is a quartz chamber configured to be placed under a vacuum. Reaction chamber 100 is situated in a furnace 102 such as a tube furnace. A tube such as a quartz test tube 104 is situated in the reaction chamber 100. Test tube 104 is oriented horizontally in the reaction chamber and has an opened-end 104a and a closed-end 104b. A vacuum pump/exhaust is operable to evacuate air from the reaction chamber 100, and in particular the open end 104a of the test tube. Situated in test tube 104 is a ceramic boat 106. In general, boat 106 is non-reactive with the precursors described below. In a particular example, boat 106 is made from alumina. A substrate 108 is supported on the boat 106. The substrate 108 is non-reactive with the precursors described below or the desired material (in this case, BNNTs) to be formed by the CCVD process. In one example the, substrate 108 is made of silicon.

Though in the example of FIG. 1 there is a single test tube 104 with a single boat 106 therein, it should be understood that multiple tubes 104 could be used and multiple boats 106 could be situated in each test tube 104. Moreover, in some examples, multiple substrates 108 could be stacked on top of one another on each boat 106.

For CCVD of BNNTs, the precursors include boron and nitrogen. In one example, the boron-containing precursor is boron oxide vapor. The boron oxide vapor is generated from volatile boron- and oxygen-containing source material 110 which is placed in the boat 106. For instance, the source material 110 includes boron powder and metal oxide powders such as magnesium oxide and iron oxide (FeO or Fe₂O₃) powders. The reactor 100 is heated to volatilize the source material 110 and release reactive boron oxide (BₓO_{y}) into test tube 104. In a particular example, the heating is to a temperature that ranges from about 1150 to about 1300° C.

The nitrogen-containing precursor flows through the reaction chamber 100. The nitrogen-containing precursor is a nitrogen-containing gas such as ammonia (NH₃) gas. In one example, test tube 104 is oriented such that the direction of the flow of the nitrogen-containing precursor is from the closed-end 104b of the tube to the opened-end 104a of the tube.

As the nitrogen-containing precursor is flowed through the reactor 100, some of it enters test tube 104 via the opened-end 104a and reacts with the boron oxide vapor derived from the source material 110 as described above. Test tube 104 traps the precursors and reaction products near substrate 108, allowing hexagonal boron nitride deposits to grow into BNNTs on substrate 108. The substrate 108 is coated with catalyst as discussed in more detail below.

In a particular example method, the reaction chamber 100 is evacuated to about 30 mTorr, and ammonia gas is provided to the reaction chamber at a flow rate of between about 100 and about 500 sccm. The reaction chamber is heated to 1150 to about 1300° C. and held at substantially constant temperature and pressure for one hour. The resulting BNNTs have small diameters between about 8 and about 30 nm.

In some examples, substrate 108 includes a catalytic coating or film on one or both surfaces, which catalyzes the formation of BNNTs. In some examples, the coating can have a thickness of about 10-about 30 nm.

One example catalytic coating is magnesium oxide. It was previously thought that magnesium oxide catalyzes the formation of BNNTs. However, it has been discovered that the magnesium oxide reacts with silicon substrates 108 to form Mg—Si—O complexes such as Mgₓ(SiO₂)_{y}, which actually act as the catalyst that catalyzes growth of BNNTs. Without being bound by any particular theory, it is thought that the metal or metal oxide constituents of the coatings break into large nanoparticles with nonuniform diameters ranging from about 10 to about 100 nm at the high temperatures in the reaction chamber 100. It is thought that these nanoparticles induce the formation of BNNTs. It is also thought that the composition of the catalyst and resulting nanoparticles affect the size of the nanoparticles, affecting the size of the BNNTs that form on the substrate 108 as catalyzed by the catalyst.

After the BNNTs are grown on the substrates 108 as discussed above, they are removed from the substrates 108 and extracted by being placed in a solution, such as an ethanol solution, and agitated by sonication or a different agitation method. The solution is then dried or evaporated away, leaving the BNNTs.

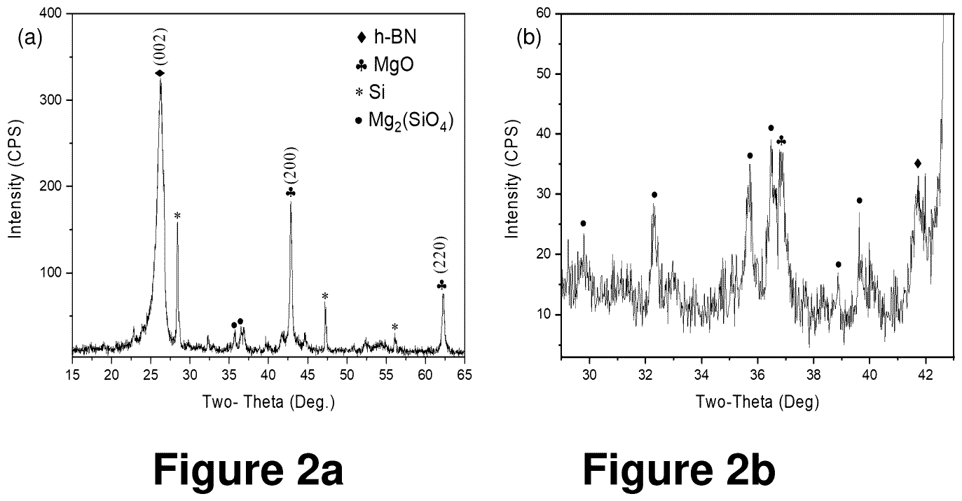

FIGS. 2A-B show x-ray diffraction spectra of BNNTs manufactured by the method described above. FIG. 2A shows spectra at wide scanning angles and FIG. 2B shows a magnified view of the spectra in FIG. 2A at 29°-43°. Analysis of the spectra confirms the presence of hexagonal boron nitride, which makes up BNNTs. The analysis also shows the presence of silicon, magnesium oxide, and magnesium silicate (Mg₂(SiO₄)), which catalyze the formation of BNNTs as discussed above.

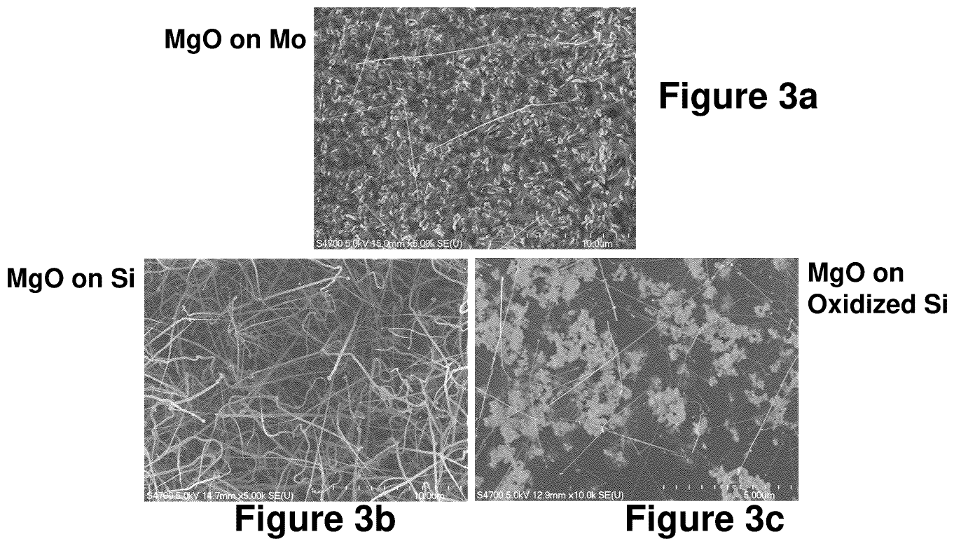

It was confirmed that Mg—Si—O complexes, and not magnesium oxide, catalyze the growth of BNNTs. Molybdenum and oxidized silicon (silicon wafers with a 500 nm thick coating of thermal oxide) substrates 108 were used along with silicon substrates in the method of manufacture disclosed above. Each substrate was coated with a magnesium oxide catalytic coating, as discussed above. FIGS. 3A-C show SEM images of BNNTs grown on each of the substrates. As shown, the molybdenum and oxidized silicon substrates 108 had almost no BNNTs, while the silicon substrates 108 had dense BNNTs. This confirms that the formation of Mg—Si—O complexes is key in catalyzing BNNT formation when magnesium oxide is used as a catalyst.

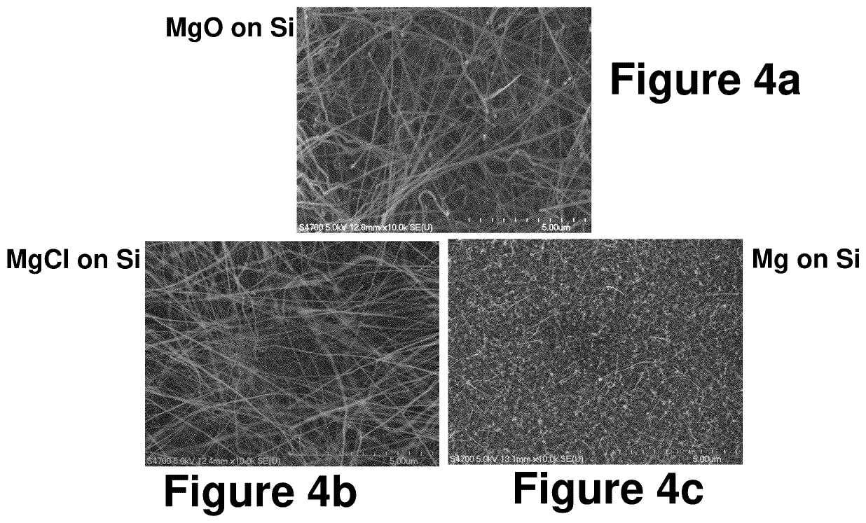

It has been discovered that other magnesium-containing catalytic coatings can catalyze the growth of BNNTs, and that changing the chemical makeup of the catalytic coating affects the diameter of the resulting BNNTs. FIGS. 4A-C show SEM images of BNNTs grown on a silicon substrate 108 with magnesium oxide, magnesium chloride (solution in water, methanol, ethanol, isopropanol etc.), and magnesium catalytic coatings. The BNNTs grown with the magnesium chloride catalytic coating had an average diameter lower than the average diameter of BNNTs grown with the magnesium oxide catalytic coating, and BNNTs grown with the magnesium catalytic films had an average diameter lower than the average diameter of BNNTs grown with the magnesium chloride catalytic coatings. Some of the BNNTs grown with the magnesium catalytic coating had very small diameters of approximately 8 nm.

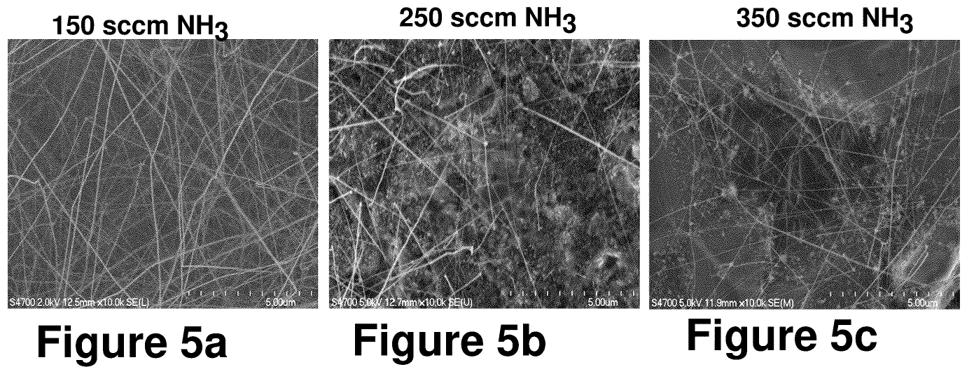

Moreover, it has been discovered that the diameter of the BNNTs formed by CCVD can be controlled by varying the flow rate of nitrogen-containing gas through reaction chamber 100. More particularly, there is an inverse relationship between BNNT diameter and nitrogen-containing gas flow rate. FIGS. 5A-C show SEM images of BNNTs grown with magnesium chloride catalytic coatings at the same magnification of 10×. The BNNTs in FIGS. 5A, 5B, and 5C were grown with an ammonia flow rate of 150 sccm, 250 sccm, and 350 sccm, respectively. As shown, the latter BNNTs (FIG. 5C) had smaller diameters on average.

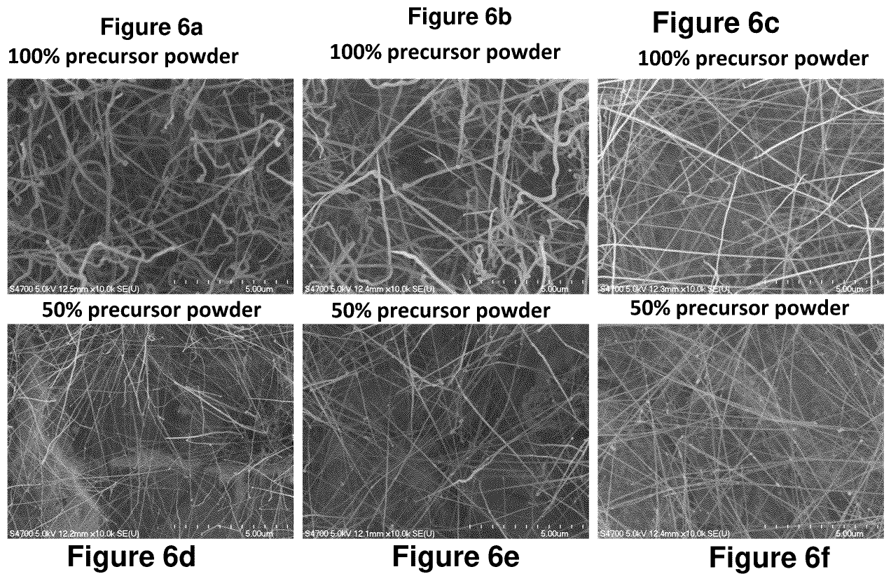

It has also been discovered that the diameter of BNNTs formed by CCVD can be controlled by varying the amount of source material 110 in boat 106. More particularly, there is a direct relationship between the amount of source material 110 in the boat 106 and BNNT diameter. FIGS. 6A-F show SEM images of BNNTs grown with magnesium chloride catalytic coatings at the same magnification of 10×. The BNNTs in FIGS. 6A-C were grown with a predetermined amount of source material 110. The BNNTs in FIGS. 6D-F were grown with 50% of the predetermined amount of source material 110. As shown, the latter BNNTs had smaller diameters on average.

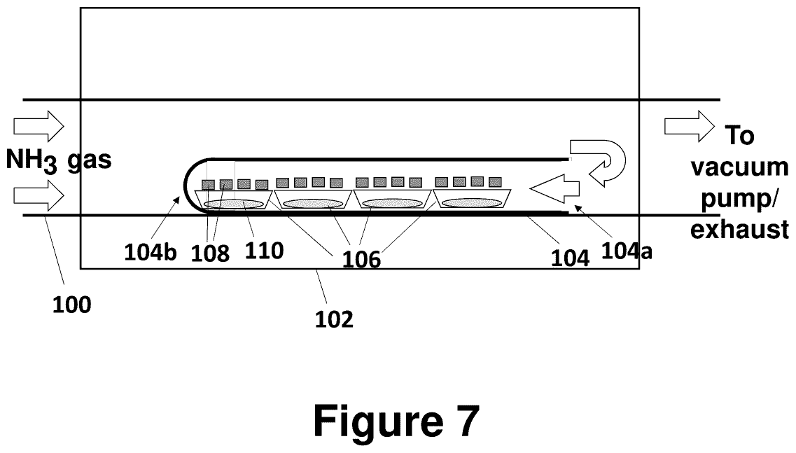

FIG. 7 shows one particular example reactor 100 setup for manufacturing small-diameter BNNTs. In FIG. 7, there are four boats 106 inside test tube 104. A total of sixteen silicon substrates 108, four supported on each boat 106, are coated with magnesium chloride catalyst. In FIG. 7, the substrates 108 are arranged in a common plane adjacent to one another over the boats 106, but in other examples, substrates 108 can be stacked on top of one another. Starting material 110 is placed in each boat 106. In one example, each boat 106 has the same amount of starting material 110, but in other examples, one or more of the boats 106 has different amounts of starting material 110. The method of manufacturing BNNTs is performed as described above.

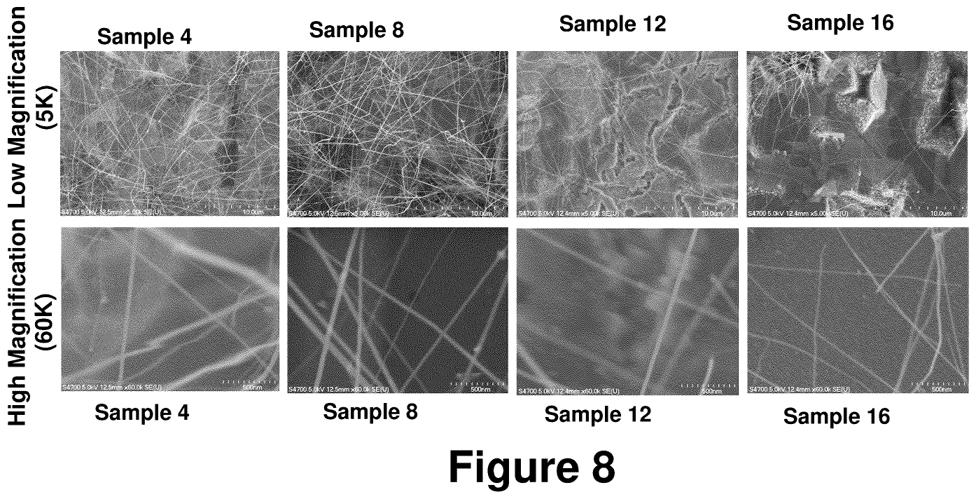

It has been discovered that the location of boat 106 within test tube 104, and more particularly the proximity of boat 106 with respect to the opened-end 104a of test tube 104, affects the size of the BNNTs grown on the substrates 108. In one example, the test tube 104 is about 12 inches long and the boats 106 are arranged along the 12-inch length. In general, the closer the substrate 108 to the opened-end 104a of the test tube 104 (and the vacuum pump/exhaust which is operable to remove reaction vapors from the test tube 104), the smaller the diameter of the BNNTs grown on that substrate 108. For the sixteen example substrates 108 shown in FIG. 7, Substrate 1 is the substrate 108 closest to the closed-end 104b of the test tube 104 and Substrates 2-16 are subsequently numbered moving towards the opened-end 104a of test tube 104. FIG. 8 shows SEM images of BNNTs grown on Substrates 4, 8, 12, 16. As shown in the top row (low magnification of 5×), the diameters of BNNTs are about 10-60 nm for Substrates 4 and 8. The diameters of the BNNTs on Substrates 12-16 were decreasing in size, with the smallest diameter BNNTs (about 10-20 nm) on Sample 16. The corresponding magnified images (60×) of these samples are shown in the bottom row.

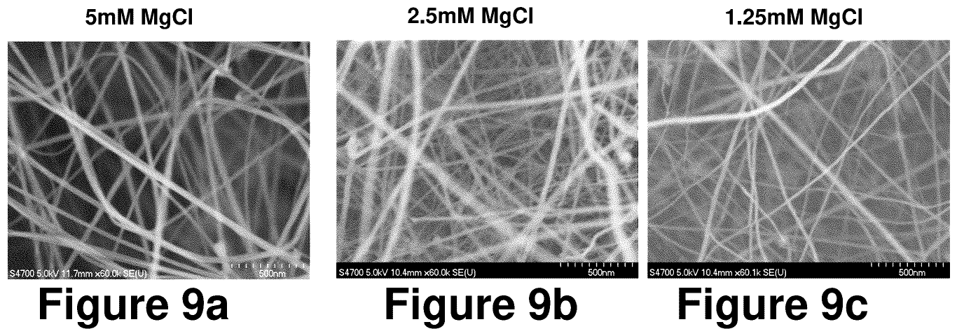

It has also been discovered that the diameter of BNNTs formed by CCVD can be controlled by varying the magnesium concentration in the catalytic coatings. More particularly, there is a direct relationship between the concentration of magnesium in the catalytic coatings and BNNT diameter. In one example where the catalytic coating is magnesium chloride, silicon substrates 108 were exposed to 5 mM, 2.5 mM, and 1.25 mM solutions of magnesium chloride so that the magnesium chloride solution dried and formed the catalytic coating on the silicon substrates 108. FIGS. 9A-C show SEM images of BNNTs grown with each of the three silicon substrates under a same magnification of 60×. As shown in FIG. 9A, the majority (e.g., greater than about 50%) of BNNTs grown with the catalytic coating formed from the 5 mM solution had diameters between about 20 and about 50 nm. As shown in FIG. 9B, the majority of BNNTs grown with the catalytic coating formed from the 2.5 mM solution had diameters between about 10 and about 40 nm. As shown in FIG. 9C, the majority of BNNTs grown with the catalytic coating formed from the 1.25 mM solution had diameters between about 10 and about 25 nm.

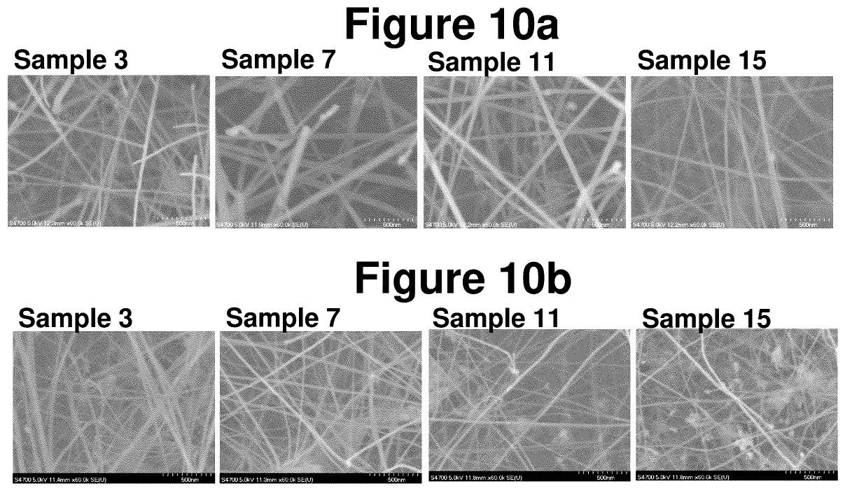

It has also been discovered that the amount of source material 110 in boat 106 can also affect the diameters of BNNTs grown on substrates 106 using the setup in FIG. 7. In one particular example, BNNTs were grown on MgO-coated silicon substrates 106. FIG. 10A shows that the diameters of the resulting BNNTs range from about 20 to about 80 nm when using 100% of the source material. Where the amount of source material 110 is reduced to 75% of the amount used in the FIG. 10B example discussed above, the diameters of the BNNTs range from about 10 to about 30 nm as shown in FIG. 10b. Consistent with the above description for silicon substrates 106 coated with MgCl, fewer source materials 110 can enable the growth of BNNTs with smaller diameters on MgO-coated silicon substrates 110.

FIGS. 10A-B also show the tendency to grow BNNTs with smaller diameters on substrates near the opened-end 104a of tube 104. For example, FIG. 10A shows that BNNTs on sample 15 are smaller in diameter than samples 7 and 11. Consistent with the above description for silicon substrates 106 coated with MgCl, BNNTs with smaller diameters are grown on MgO-coated silicon substrates 106 located near the opened-end 104a of tube 104.

As used herein, the terms “approximately” and “about” have the typical meaning in the art, however in a particular example “about” or “approximately” can mean deviations of up to 10% of the values described herein.

The preceding description is exemplary rather than limiting in nature. Variations and modifications to the disclosed examples may become apparent to those skilled in the art that do not necessarily depart from the essence of this invention. The scope of legal protection given to this invention can only be determined by studying the following claims.

What is claimed is:

1. A reactor for catalytic chemical vapor deposition of nanotubes, comprising:
a reaction chamber configured to be placed under vacuum;
at least one tube situated in the reaction chamber, wherein the tube has a first closed end and a second open end;
at least one boat situated in the tube;
at least one substrate situated on each of the at least one boats; and
source material in each boat of the at least one boats.

2. The reactor of claim 1, wherein the at least one tube is situated horizontally in the reaction chamber.

3. The reactor of claim 1, wherein the at least one substrate includes multiple substrates.

4. The reactor of claim 3, wherein the at least one substrate includes multiple substrates arranged in a common plane.

5. The reactor of claim 3, wherein the at least one substrate includes multiple stacked substrates.

6. The reactor of claim 1, wherein the at least one substrate is coated with a catalytic coating.

7. The reactor of claim 6, wherein the catalytic coating includes magnesium.

8. The reactor of claim 1, wherein the at least one substrate is silicon.

9. The reactor of claim 1, wherein the at least one boat is a ceramic boat.

10. The reactor of claim 1, wherein the tube has a first closed end and a second open end.

11. The reactor of claim 1, wherein the source material is boron- and oxygen-containing source material.

12. The reactor of claim 11, wherein the source material includes metal oxide powder.

13. A method for catalytic chemical vapor deposition of boron nitride nanotubes, comprising:
orienting a tube in the reaction chamber, the tube having an open end and a closed end;
situating at least one boat in the tube, at least one silicon substrate situated on each of the at least one boats, wherein boron- and oxide-containing source material is arranged in the at least one boat;
heating the reaction chamber to volatilize the source material and release boron oxide into the tube; and
flowing a nitrogen-containing precursor through the reaction chamber such that the nitrogen-containing precursor reacts with the boron oxide and boron nitride nanotubes are deposited onto the at least one substrate.

14. The method of claim 13, wherein the tube is oriented in the reaction chamber such that a direction of flow of the nitrogen-containing precursor is from the closed end of the tube towards the open end of the tube.

15. The method of claim 13, wherein the at least one silicon substrate includes a catalytic coating.

16. The method of claim 15, wherein the catalytic coating includes magnesium.

17. The method of claim 16, wherein the catalytic coating includes magnesium oxide, and wherein the magnesium oxide reacts with the silicon substrate to form Mg—Si—O complexes, the Mg—Si—O complexes acting as catalysts.

18. The method of claim 16, wherein the catalytic coating includes magnesium chloride.

19. The method of claim 13, wherein a concentration of the magnesium chloride is about 1.25 mM, and wherein a diameter of the boron nitride nanotubes is between about 10 to about 25 nm.

20. The method of claim 13, wherein the catalytic nitrogen-containing precursor is ammonia gas.

21. The method of claim 13, further comprising placing the reaction chamber under vacuum.

22. The method of claim 13, wherein the boron nitride nanotubes have a diameter less than about 35 nm.

23. The method of claim 21, wherein the boron nitride nanotubes have a diameter of less than about 10 nm.

24. The method of claim 13, wherein boron nitride nanotubes deposited on a first substrate of the at least one substrates have a smaller diameter than boron nitride nanotubes deposited on a second substrate of the at least one substrates, and wherein the first substrate is further from an exhaust situated in the reaction chamber than the second substrate.

25. The method of claim 13, wherein a first boat of the at least one boats includes a first amount of source material and a second boat of the at least one boats includes a second amount of source material that is about 50% of the source material of the first amount of source material, and wherein boron nitride nanotubes on a substrate of the at least one substrates situated on the first boat have larger diameters that boron nitride nanotubes on a substrate of the at least one substrate situated on the second boat, on average.

26. The method of claim 13, wherein a flow rate of the nitrogen precursor is about 350 sccm, and the diameter of the boron nitride nanotubes are between about 20 and about 25 nm.
